(19) United States
(12) Patent Application Publication
(10) Pub. No.: US 2008/0254589 A1
(43) Pub. Date: Oct. 16, 2008

(54) METHOD FOR MANUFACTURING COLLARS OF DEEP TRENCH CAPACITORS

(76) Inventors: Jen-Jui Huang, Taoyuan County (TW); Chih-Ching Lin, Taoyuan County (TW)

Correspondence Address: NORTH AMERICA INTELLECTUAL PROPERTY CORPORATION, P.O. BOX 506, MERRIFIELD, VA, 22116, US

(21) Appl. No.: 11/829,067

(22) Filed: Jul. 26, 2007

(30) Foreign Application Priority Data
Apr. 14, 2007 (TW) 096113241

(51) Int. Cl. H01L 21/20

(52) U.S. Cl. 438/389; 257/E21.09

(57) ABSTRACT

A method for manufacturing collars of deep trench capacitors includes providing a substrate with a deep trench in which there is a trench capacitor in the bottom; forming an inner wall layer completely covering the deep trench and the substrate; forming a hard mask layer on the surface of the inner wall layer; performing a selective implanting but not on the hard mask layer on the wall of the deep trench; performing a selective wet etching to remove the not implanted hard mask layer; and performing an anisotropic dry etching to substantially remove the inner wall layer on the bottom of the deep trench so as to partially expose the trench capacitor and to substantially retain the collars of the deep trench capacitors intact.

### BACKGROUND OF THE INVENTION

1. Field of the Invention

The present invention relates to a method for manufacturing a collar of a deep trench capacitor. In particular, the present invention relates to a method for substantially protecting the collar of a deep trench capacitor by a selective wet etching.

2. Description of the Prior Art

There are two kinds of capacitors conventionally used in the dynamic random access memory (DRAM). One of them is called the deep trench capacitor. In the formation steps of the deep trench capacitor, an etchant such as fluorocarbon is used to construct the collar part and simultaneously a layer of polymers is deposited to protect the collar at the top of the trench. Usually, the polymer after the etching is accumulated in the trench, so the etching time should be extended after the formation of the collar to remove the residues at the collar. However, this would do damage to the collar of the capacitor trench.

Therefore, it is needed to provide a novel method for manufacturing the collar of the deep trench capacitor to solve the problem.

### SUMMARY OF THE INVENTION

The present invention accordingly provides a method for manufacturing collars of deep trench capacitors. A hard mask layer along with an anisotropic dry etching procedure may substantially protect the collars of deep trench capacitors from damage. The method of the present invention includes:

providing a substrate with a deep trench in which a trench capacitor is in the bottom;

forming an inner wall layer completely covering the deep trench and the substrate;

forming a hard mask layer on the surface of the inner wall layer;

performing a selective tilt angle ion implantation so that the hard mask layer on the wall of the deep trench is not implanted;

performing a selective wet etching to remove the not implanted hard mask layer;

and performing an anisotropic dry etching to substantially remove the inner wall layer on the bottom of the deep trench so as to partially expose the trench capacitor and to substantially retain the collar of the deep trench capacitor intact.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1a to 1e illustrate a preferred embodiment of the method for manufacturing collars of deep trench capacitors of the present invention.

### DETAILED DESCRIPTION

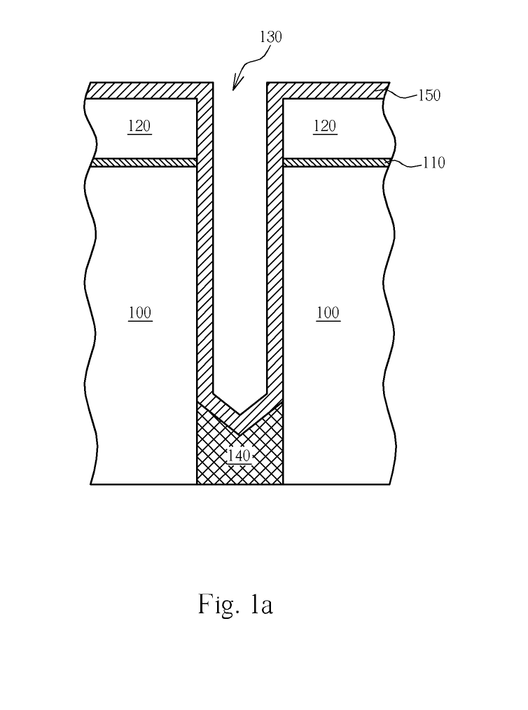

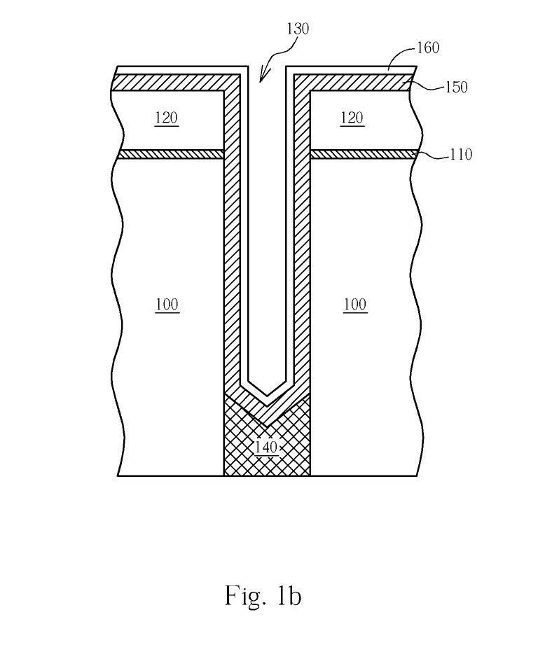

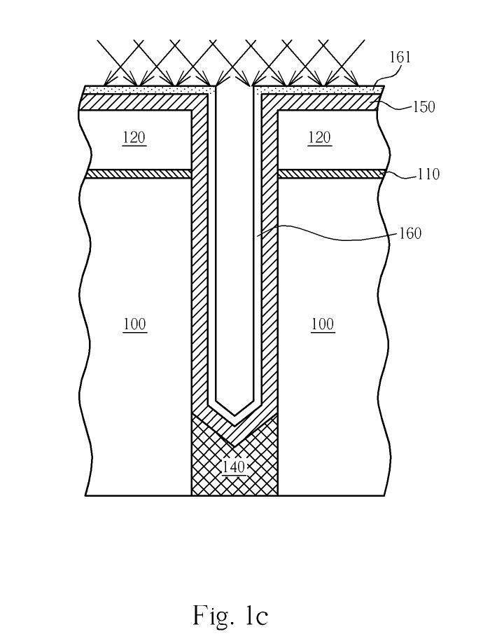

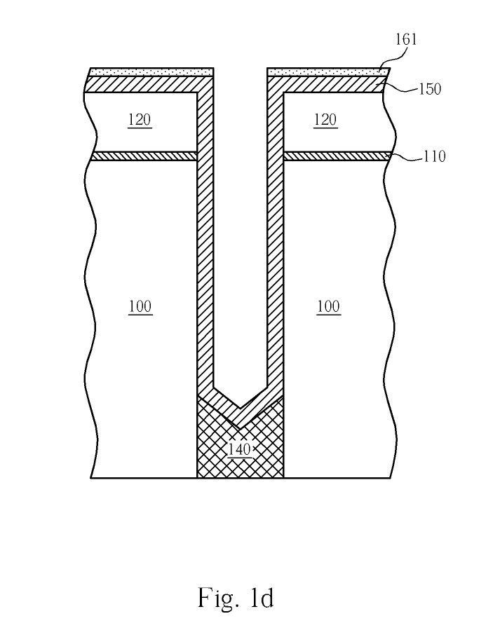

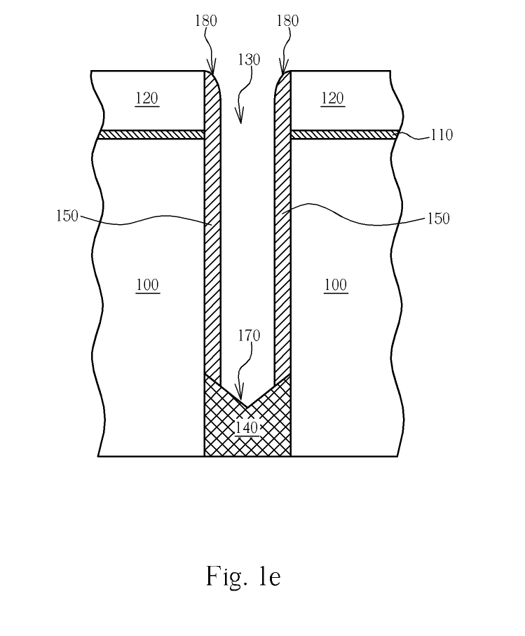

The present invention provides a method for manufacturing collars of deep trench capacitors. Because of the selective etching procedure, the collars of the deep trench capacitors may substantially be protected from the damage of over-etching. FIG. 1a to 1e illustrate a preferred embodiment of the method for manufacturing collars of deep trench capacitors of the present invention. First, in FIG. 1a the substrate 100 is provided. The substrate 100 usually comprises a semiconductor substrate, such as Si. A pad oxide 110, a silicon nitride layer 120 and a deep trench 130 are formed by conventional methods. The deep trench 130 has a trench capacitor 140 in the bottom. The trench capacitor 140 usually includes a conductive material, such as poly-Si.

Then an inner wall layer 150 completely covering the deep trench 130 and the substrate 100 is formed by a method such as CVD. The inner wall layer 150 usually includes an oxide material, such as silicon oxide, with a thickness of about 250 Å.

Please refer to FIG. 1b. A hard mask layer 160 is formed on the surface of the inner wall layer 150. The hard mask layer 160 usually includes poly-Si, preferably by a method such as CVD to have a thickness of about 140 Å.

Please refer to FIG. 1 c. A selective tilt angle ion implantation is performed on the hard mask layer 160 on the inner wall layer 150 to form a doped hard mask layer 161. However, the hard mask layer 160 on the inner wall of the deep trench 130 is not implanted. If BF₂⁺ is used as the dopant, the incident angle may preferably be in the range of about 0-10°.

Because the doped hard mask layer 161 exhibits a distinctive feature from that of the not doped hard mask layer 160, as shown in FIG. 1 d, a selective wet etching can be performed to remove the not implanted hard mask layer 160. An etchant of NH₄OH/H₂O of concentration 1/300 may be used for about 15 minutes to perform the selective wet etching, preferably to completely remove the not doped hard mask layer 160 and substantially retain the doped hard mask layer 161 intact. For example, the doped hard mask layer 161 may have a remaining thickness of 105 Å to be the hard mask of the next step.

As shown in FIG. 1e, an anisotropic dry etching is performed using the doped hard mask layer 161 as the hard mask to substantially remove the inner wall layer 150 on the bottom of the deep trench so as to partially expose the trench capacitor 170. An etching gas such as C₄F₆/O₂/Ar may be used to perform the anisotropic dry etching. Because the dry etching is anisotropic, the doped hard mask layer 161 is etched away as well in addition to the inner wall layer on the bottom of the deep trench and the exposed trench capacitor 170. Preferably, the doped hard mask layer 161 is completely removed, which may further omit the step to remove it. A shoulder 180 is formed near the opening of the deep trench 130 due to the etching.

The collars of the deep trench capacitors are substantially retained and protected from the damage of etching due to the protection of the hard mask layer 161. The method for manufacturing a collar of a deep trench capacitor of the present invention may be processed by the conventional methods for a deep trench capacitor.

Those skilled in the art will readily observe that numerous modifications and alterations of the device and method may be made while retaining the teachings of the invention.

What is claimed is:

1. A method for manufacturing a collar of a deep trench capacitor, comprising:
providing a substrate with a deep trench in which a trench capacitor is in the bottom;
forming an inner wall layer completely covering said deep trench and said substrate;
forming a hard mask layer on the surface of said inner wall layer;
performing a selective tilt angle ion implantation so that said hard mask layer on the wall of said deep trench is not implanted;
performing a selective wet etching to remove said not implanted hard mask layer;
and performing an anisotropic dry etching to substantially remove said inner wall layer on the bottom of said deep trench so as to partially expose said trench capacitor and to substantially retain said collar of said deep trench capacitor intact.

2. The method for manufacturing a collar of a deep trench capacitor of claim 1, wherein said substrate is a semiconductor substrate.

3. The method for manufacturing a collar of a deep trench capacitor of claim 1, wherein said trench capacitor comprises poly-Si.

4. The method for manufacturing a collar of a deep trench capacitor of claim 1, wherein said inner wall layer comprises an oxide.

5. The method for manufacturing a collar of a deep trench capacitor of claim 1, wherein said hard mask layer comprises poly-Si.

6. The method for manufacturing a collar of a deep trench capacitor of claim 1, wherein performing said selective tilt angle ion implantation is carried out utilizing BF₂⁺.

7. The method for manufacturing a collar of a deep trench capacitor of claim 1, wherein performing said selective tilt angle ion implantation is carried out with an incident angle about 0-10°.

8. The method for manufacturing a collar of a deep trench capacitor of claim 1, wherein performing said selective wet etching is carried out by using an etchant of NH₄OH/H₂O of concentration 1/300.

9. The method for manufacturing a collar of a deep trench capacitor of claim 1, wherein performing said anisotropic dry etching is carried out by using an etching gas of C₄F₆/O₂/Ar.

10. The method for manufacturing a collar of a deep trench capacitor of claim 1, wherein performing said anisotropic dry etching substantially removes said hard mask.
